(19) United States
(12) Patent Application Publication
(10) Pub. No.: US 2025/0087521 A1
(43) Pub. Date: Mar. 13, 2025

(54) EXPANDABLE WAFER BONDER

(71) Applicant: Tokyo Electron Limited, Tokyo (JP)

(72) Inventors: Christopher NETZBAND, Albany, NY (US); Adam GILDEA, Albany, NY (US)

(73) Assignee: Tokyo Electron Limited, Tokyo (JP)

(21) Appl. No.: 18/367,306

(22) Filed: Sep. 12, 2023

(51) Int. Cl. H01L 21/683; H01L 21/67

(52) U.S. Cl. CPC H01L 21/6838; H01L 21/67092; H01L 21/67259

(57) ABSTRACT

Expandable semiconductor chucks are disclosed. The semiconductor chucks can include a first portion comprising a plurality of first couplers configured to receive a corresponding plurality of actuators. The semiconductor chucks can include a second portion circumscribed about the first portion, the second portion comprising a plurality of segments. Each segment can include a wafer holder to selectively couple the respective segment to a semiconductor wafer. Each segment can include a second coupler to receive one or more of the plurality of actuators. The actuators can extend to increase a dimension between the first portion and the second portion and retract to decrease a dimension between the first portion and the second portion.

### TECHNICAL FIELD

This disclosure relates to semiconductor wafer handling devices. The semiconductor wafer handling devices can interface with semiconductor wafers during bonding or other operations.

### BACKGROUND

Fabrication of semiconductor devices can include wafer stacking, bonding, or other handling or operations which can impart stress or cause displacement of the wafers. Such stress or displacement can impact alignment, performance, and yield in semiconductor devices. Improvements in the art are desired.

### SUMMARY

In order to continue scaling down semiconductor devices, device structures can be designed to extend in their vertical direction, such as upwards from the substrate on which they are fabricated. Such designs can employ various stacked layers, such as any number of stacked wafers. The stacked wafers can be coupled to one another via van der Waals forces, electrostatic forces, or chemical bonds at a bonding interface. Bonding (e.g., adhesive) materials can mechanically couple wafers, or ohmic connections can be formed between wafers. Wafers can be disposed between wafer chucks (e.g., a top wafer chuck and a bottom wafer chuck) to impart thermal energy, pressure, maintain wafer flatness, or otherwise encourage wafer bonding. The respective chucks can control wafer alignment, temperature, pressure, rotation, alignment, flatness, and so forth. The top chuck can include an opening to receive a striker to cause the top wafer to couple to the lower wafer (e.g., at a wafer center point). The top wafer can deflect towards the lower wafer to couple thereto, and the coupling can thereafter extend radially outward based on the wafer-wafer forces, such as those described above. Thus, a propagation wave (also referred to as a lamination wave) can propagate outward from an initial coupling between the wafers.

In general, the propagation wave can be represented as a lateral wave which propagates incident to a vertical movement of the wafer. However, where the outer portion of the wafer is fixed by a wafer holder, the propagation wave can cause an initial lateral tensile stress of the wafer as the striker causes the wafer to extend a radial lateral dimension to deflect towards another wafer, and a subsequent lateral compressive stress, as the propagation wave moves towards the fixed portion of the wafer. An actuator disposed between a central portion of the chuck, and an outer portion of the chuck can adjust a lateral position of the portion of the wafer fixed by the wafer holder. That is, a wafer holder along an outer edge of the wafer can displace outwards. The positional adjustment (e.g., outward displacement) can, in turn, affect a corresponding strain-related displacement between features of the wafers, or impart electrical properties to the wafers. The operation of the actuator can be controlled based on predefined timing of the propagation wave relative to the striker, or responsive to propagation sensors. For example, the actuators can operate to maintain a relatively constant stress throughout the wafer, or to reduce a stress imparted to all or a portion (e.g., an outermost portion) of the wafer. Various outer portions of the chuck can radially surround the inner portion and can displace a same or different amount from one another. For example, various segments of the outer portion can extend radially outward a same or different amount.

One aspect of the present disclosure is directed to a semiconductor chuck for fabricating semiconductor devices. The semiconductor chuck includes a first portion comprising a plurality of first couplers configured to receive a corresponding plurality of actuators. The semiconductor chuck includes a second portion circumscribed about the first portion. The second portion includes multiple segments. Each of the segments includes a wafer holder to selectively couple the respective segment to a semiconductor wafer. Each of the segments includes a second coupler to receive one or more of the plurality of actuators. The actuators can extend to increase a dimension between the first portion and the second portion. The actuators can retract to decrease a dimension between the first portion and the second portion.

The actuators of the semiconductor chuck can include a piezo electric element.

The wafer holder of the semiconductor chuck can include a vacuum pad.

The semiconductor chuck can include or interface with one or more processors. The processors can be configured to cause a striker to displace a first semiconductor wafer from the facing. The processors can be configured to cause an actuation of the wafer holders to decouple from the semiconductor wafer. The decupling can be subsequent to the displacement of the first semiconductor wafer at the striker. The decupling can be prior to an arrival of a propagation wave at the wafer holders.

The semiconductor chuck can include or interface with a sensor to detect a propagation wave. The actuation of the wafer holders can be responsive to a signal detected by the sensor.

The semiconductor chuck can include or interface with a first sensor to detect a wafer height at a first point along the wafer. The semiconductor chuck can include or interface with a second sensor to detect a second wafer height at a second point along the wafer disposed radially outward from the first sensor. The semiconductor chuck can include or interface with the one or more processors to determine a propagation speed based on an elapsed time between a first detection of the first sensor and a second detection of the second sensor.

A first of the plurality of actuators can be configured to extend a first distance. A second of the plurality of actuators can be configured to extend a second distance, different from the first distance.

A first of the plurality of actuators can be configured to extend at a first rate. A second of the plurality of actuators can be configured to extend at a second rate, different from the first rate.

The semiconductor chuck can include or interface with one or more processors configured to cause a striker to displace a first semiconductor wafer from the facing. The one or more processors can cause an actuation of the actuators to decouple the semiconductor wafer subsequent to the displacement of the first semiconductor wafer at the striker.

Another aspect of the present disclosure is directed to a system. The system includes a semiconductor chuck for fabricating semiconductor devices. The semiconductor chuck includes an inner portion. The semiconductor chuck includes an outer portion comprising a plurality of segments, each of the plurality of segments being coupled to the inner portion by a respective actuator. The semiconductor chuck includes one or more processors coupled with memory. The one or more processors can detect an indication of a propagation wave. The one or more processors can engage one or more of the actuators responsive to the detection.

The actuators can include a piezo electric element.

The indication of a propagation wave can include a detection of a time elapsed from an instantiation of the propagation wave of a first wafer.

The indication of a propagation wave can include a detection of the instantiation of the propagation wave incident to an engagement, by the one or more processors, of a striker.

The indication of a propagation wave can include a distance between the semiconductor chuck and a first wafer and a comparison of the distance to a threshold.

The detection of the indication of the propagation wave can include a detection of the propagation wave at a first point along a first wafer. The detection of the indication of the propagation wave can include a detection of the propagation wave at a second point along the first wafer, along a same axis as the first point. The detection of the indication of the propagation wave can include a determination of a time elapsed between the first point and the second point.

The indication of the propagation wave can include an indication of propagation wave in a plurality of radial directions of a first wafer.

The one or more processors can selectively engage the wafer holders responsive to the indication of the propagation wave.

Another aspect of the present disclosure is directed to a method. The method includes instantiating, at an instantiation point, wafer bonding between a first wafer and a second wafer, wherein the first wafer is coupled to a plurality of segments of a wafer chuck which are coupled to a fixed portion of the wafer chuck. The method includes detecting a propagation wave originating from the instantiation point. The method includes adjusting a position of one or more of the plurality of segments of the wafer chuck responsive to the detection of the propagation wave.

The method can include instantiating the wafer bonding comprises engaging a striker to deflect the first wafer towards the second wafer. The detection of the propagation wave can include detecting a distance from the first wafer to the wafer chuck in a plurality of axes of the first wafer.

The plurality of segments of the wafer chuck can be coupled to the fixed portion of the wafer chuck by a plurality of piezo electric actuators. The adjustment to the position of the one or more of the plurality of segments can be performed prior to an arrival of the propagation wave at each of the one or more of the plurality of segments.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Indeed, various features of the figures may be intentionally emphasized to depict various features thereof. Unless indicated as representing the background art, the figures represent aspects of the disclosure. For purposes of clarity, not every component may be labeled in every drawing. In the drawings:

FIG. 1 illustrates an exploded diagram of a system for wafer bonding, in accordance with some embodiments.

FIG. 2 illustrates a top view of a propagation wave generated by the system of FIG. 1, in accordance with some embodiments.

FIG. 3 illustrates a cross sectional view of the propagation wave of FIG. 2, in accordance with some embodiments.

FIG. 4 illustrates a top view of a facing of a semiconductor chuck, in accordance with some embodiments.

FIG. 5 illustrates a cross sectional view of a semiconductor chuck, in accordance with some embodiments.

FIG. 6 illustrates a method of wafer bonding, in accordance with some embodiments.

FIG. 7 illustrates a block diagram illustrating an architecture for a computer system that can be employed to implement elements of the systems and methods described and illustrated herein.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Likewise, although the Figures and aspects of the disclosure may show or describe devices herein as having a particular shape, it should be understood that such shapes are merely illustrative and should not be considered limiting to the scope of the techniques described herein. Although certain figures show various operations of a linear actuator to reduce a stress of a semiconductor wafer, other operations contemplated, and indeed the techniques described herein may be implemented to achieve various stress profiles. Moreover, although references herein are made to “top,” “bottom,” “vertical,” “lateral” and the like, such descriptions are intended to describe one or more depicted embodiments, and not intended to provide limiting effect. For example, in some embodiments, the top chuck and bottom chuck, or individual features thereof, may be inverted, rotated, skewed, or so forth.

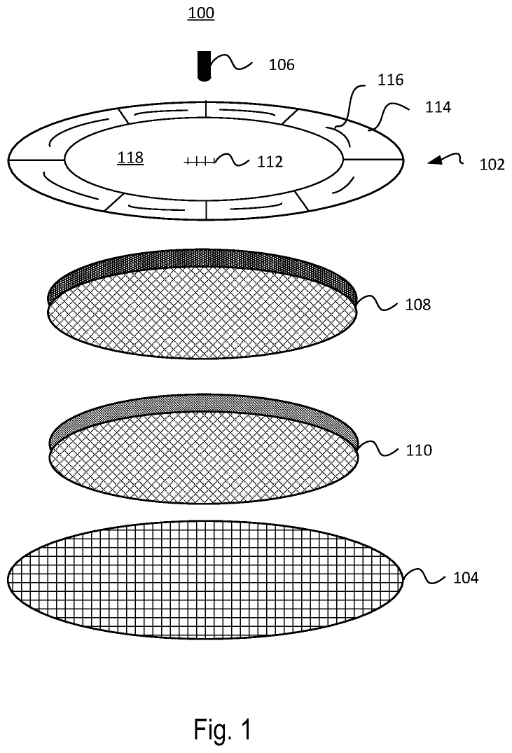

FIG. 1 illustrates an exploded diagram of a system 100 for wafer bonding, in accordance with some embodiments. The system 100 includes a top chuck 102 configured to interface with a bottom chuck 104. The top chuck 102 and bottom chuck 104 can perform various operations, such as temporary or permanent bonding of wafers such as the depicted top wafer 108 and bottom wafer 110. According to various embodiments, the top wafer 108 and bottom wafer 110 can include semiconductor wafers at various stages of fabrication. For example, either wafer can include a silicon, silicon-germanium, or other intrinsic semiconductor wafer, a wafer with various circuits formed along an active surface thereof, a wafer with various metallization layers formed over such active circuits, etc.

The top chuck 102 can be operatively coupled with a striker 106 to couple a top wafer 108 to a bottom wafer 110, the top wafer 108 being operatively coupled to the top chuck 102 and the bottom wafer 110 being operatively coupled to the bottom chuck 104. According to various embodiments, the striker 106 can be replaced by various wafer coupling mechanisms, such as a thermal element or a lateral surface of the top chuck 102 or bottom chuck 104 configured to cause a coupling at a predefined point, such as a center of the wafers 108, 110 (e.g., a slight convexity to a surface).

The top chuck 102 can include an outer portion 114 which includes a wafer holder such as an electro-static, mechanical, or vacuum-based holder, such as the vacuum pads 116 of FIG. 1. Although eight segments of the outer portion 114 are depicted, various embodiments, can employ outer portions 114 having various number of segments. Further, various outer portions 114 can include any number of vacuum pads 116. For example, the outer portion 114 can include a repeating pattern of vacuum pads 116. Likewise, the inner portion 118 can include such vacuum pads 116 of a same or different pattern or type.

The outer portion 114 can circumscribe an inner portion 118 which can include further wafer holders (not depicted) of a same or different type as the outer portion 114. Any of the wafer holders described herein can be selectively engaged. For example, wafer holders of the inner portion 118 can be disengaged to aid the displacement of the top wafer 108, outwards towards the bottom wafer 110 upon a receipt, through an opening 112 of the top chuck 102, of the striker 106.

One or more linear actuators (not depicted) can cause the displacement of one or more segments of the outer portion 114 of the top chuck 102. For example, the linear actuators can cause an outward movement of laterally opposite segments (along with any wafer holders thereof), which may reduce or eliminate a compressive force incident to a propagation wave 202 between the top wafer 108 and the bottom wafer 110.

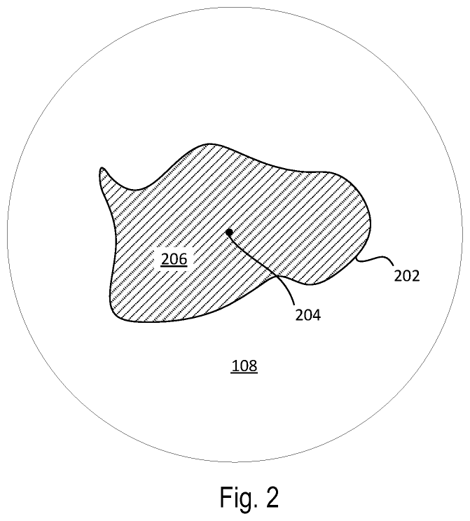

FIG. 2 illustrates a top view of a propagation wave 202 generated by the system of FIG. 1, in accordance with some embodiments. The propagation wave 202 refers to a lateral boundary of an interface between the top wafer 108 and bottom wafer 110 (not depicted). For example, upon the striker 106 deflecting the top wafer 108 towards the bottom wafer 110, the top wafer 108 can couple to the bottom wafer 110 at a central location 204 thereof (where the striker 106 is centrally located relative to the wafers 108, 110). The lateral location at the center of the top wafer 108 and bottom wafer 110 or other location which initiates the inter-wafer lamination (e.g., corresponding to the striker 106) may be referred to as an instantiation point. The propagation wave 202 can extend generally radially outward, such that the propagation wave 202 defines a lateral boundary a coupled portion 206 of the top wafer 108 and bottom wafer 110, and a portion of each of the top wafer 108 and bottom wafer 110 which are not coupled. The propagation wave 202 may also be referred to as a lamination wave, where the propagation refers to a lamination formed from the combination of the top wafer 108 and bottom wafer 110.

In some embodiments, the propagation wave 202 can propagate at a substantially same rate in each direction, such that the propagation wave 202 can be substantially concentric to the outer edge of the circular wafers 108, 110. In some embodiments, as depicted, the propagation wave 202 may propagate are different rates in different lateral directions based on non-uniform pressure or temperature variations, thickness variations, or so forth. That is, the propagation wave 202 can travel at different effective speeds towards the outer edge of the, for example, top wafer 108. Where a radial extremity of the top wafer 108 is coupled, via a wafer holder such as a vacuum pad 116, to the outer portion 114 of the top chuck 102 (not depicted), the propagation wave 202 may arrive at each of the segments of the outer portion 114 at a different time. Thus, as is described herein, each segment can be operated responsive to a detection of the propagation wave 202 or based on any inter-segment relationships or limits.

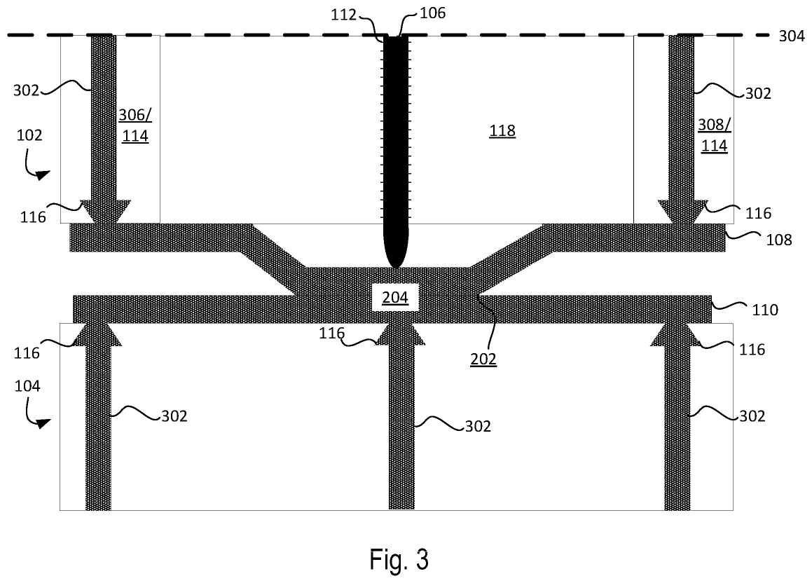

FIG. 3 illustrates a cross sectional view of the propagation wave 202 of FIG. 2, in accordance with some embodiments. Further included in the view are the top chuck 102 and the bottom chuck 104 vertically bounding the top wafer 108 and bottom wafer 110. The bottom chuck 104 is coupled to the bottom wafer 110 by various vacuum pads 116 coupled to vacuum lines 302 extending through the bottom chuck 104. The various vacuum lines 302 may be individually actuated, or collectively controlled (e.g., so that all or a portion of lines are engaged together). The vacuum pads 116 are shown at lateral extremes of the bottom chuck 104, vertically corresponding to the segments of the outer portion 114 of the top chuck 102, as well as to portions of the bottom chuck 104 vertically corresponding to the inner portion 118 of the top chuck 102. Although not depicted, for clarity, the inner portion 118 of the top chuck 102 can include vacuum pads 116. Further, in various embodiments, various other wafer holders can be substituted for any of the vacuum pads 116 described with regard to the various illustrative examples herein.

The striker 106 is shown in an engaged state, extending through the opening 112 of the top chuck 102 causing the downward deflection of the top wafer 108 to couple to the bottom wafer 110. The deflection extends a lateral dimension of the top wafer 108 according to a stress-strain relationship of the wafer. That is, absent a movement of the outer portion 114, the portion of the top wafer 108 adhered to the top chuck 102 and the portion of the top wafer 108 extending from the top chuck 102 to the propagation wave 202 may be laterally compressed towards the fixed location of the vacuum pad 116. Consequently, accumulated stress or misalignment of features between the top wafer 108 and bottom wafer 110 may impact a performance, reliability, or yield of various semiconductor devices. By laterally adjusting a position of the segments of the outer portion 114 of the top chuck 102 relative to the inner portion 118 of the top chuck 102 (e.g., outwards), such compression or accumulation of compressive stresses may be reduced or eliminated. For example, a linear actuator (not depicted) of the top chuck 102 can adjust the location of one or more segments of the outer portion 114 relative to the inner portion 118.

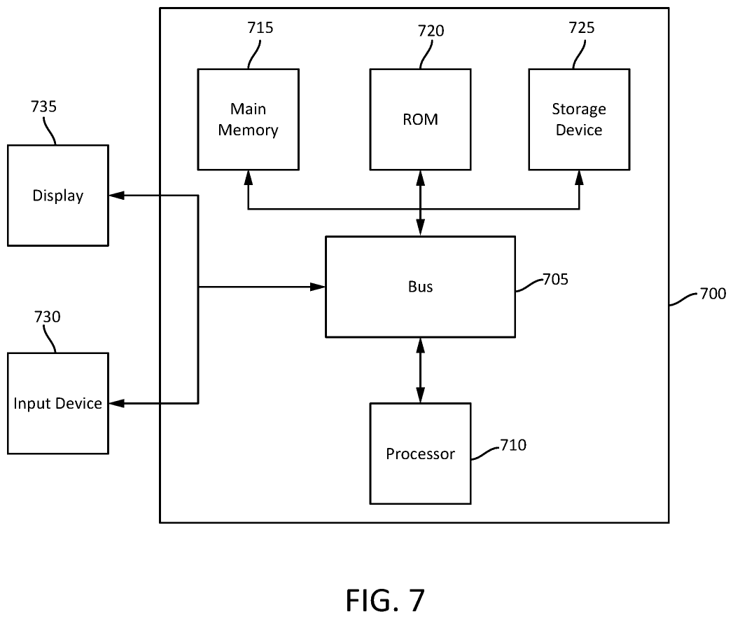

The depicted cut line 304 can exclude some portions of the top chuck 102. Further, some portions may not be depicted in the figure. For example, the cut line 304 can exclude one or more interconnections between the various vacuum lines 302 or, connections between the depicted left segment 306 and right segment 308 and the inner portion 118 of the top chuck 102. Further, sensors configured to detect a speed or position of the propagation wave 202, can be disposed above or below the cut line 304. Any of such components, or further components still, may be connected to one or more processors, coupled to memory, configured to actuate, monitor, or otherwise control the various components. For example, the processor (which may also be referred to as a controller, without limiting effect), can be or include the processor 710 of FIG. 7.

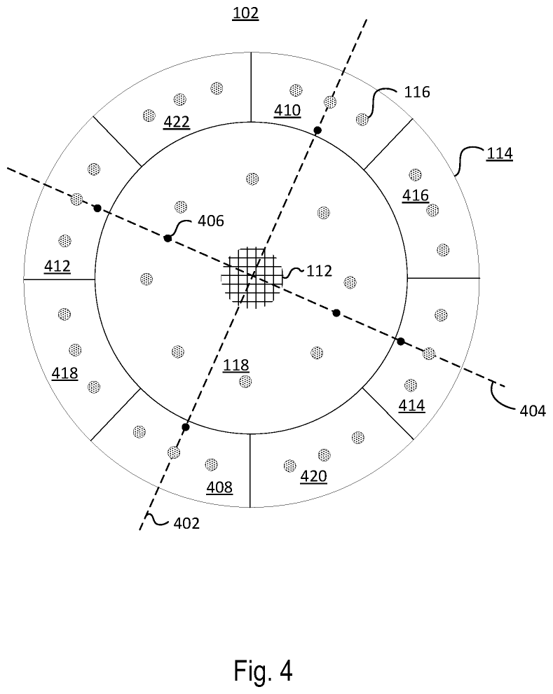

FIG. 4 illustrates a top view of a facing of a semiconductor chuck, in accordance with some embodiments. For example, the chuck can be a top chuck 102, wherein the facing is configured to interface with a top wafer 108. The various segments of the outer portion 114 are disposed along various radial axes of the top chuck 102. For example, a first pair of segments 408, 410 of the outer portion 114 are disposed on opposite ends of the inner portion 118 along a first radial axis 402, and another pair of segments 412, 414 of the outer portion 114 are disposed on opposite ends of the inner portion 118 along a second radial axis 404, which is perpendicular to the first radial axis 402 along a same lateral plane along a facing of the top chuck 102. Any number of further segments may be present in the outer portion 114. For example, a third pair of segments 416, 418 and fourth pair of segments 420, 422 are depicted. In some embodiments, segments may not be so paired, as in an embodiment with an odd number of segments.

In some embodiments, one or more segments of the outer portion 114 may be operatively coupled to another segment of the outer portion 114. For example, adjacent segments 410 and 416 may be operatively coupled to limit a positional difference (e.g., to avoid imparting stress to a wafer along a boundary between the segments). One or more segments of the outer portion 114 disposed along or proximal to an axis can be operatively coupled to maintain a center position of the wafer. For example, oppositely disposed segments of the outer portion 114 can move inwards or outwards at a same rate or amount. In various embodiments, the outer portion 114 can include additional or fewer segments. The segments, collectively, circumscribe the inner portion. That is, the outer portion 114 laterally surrounds the inner portion. Such circumscription may include gaps. For example, in either of a retracted or extended state of the various linear actuators, an inter-segment spacing may be present in the outer portion 114.

Each segment can include or omit various features disclosed herein. For example, one or more segments can include or omit a vacuum pad 116, linear actuator, propagation sensor, or so forth.

In various embodiments the various segments, along with the inner portion 118, can include various sizes, shapes, numbers, etc. of vacuum pads 116. For example, various embodiments can include circular, curvilinear, rectangular, or other shaped pads. Each vacuum pad 116 may operatively connect to a vacuum line 302 connecting to further vacuum pads 116, such that the vacuum pad 116 is operatively connected to the further vacuum pads 116. As depicted, the inner portion 118 can include further vacuum pads 116. Any of the various vacuum pads 116 can be coupled to a controller such as the processor 710 of FIG. 7. The controller can cause the release of the vacuum of the vacuum pad 116 based on a time of a striker 106 engagement or other initiation of a propagation wave 202 or based on a detection of the propagation wave 202, or an indication thereof, such as a distance between a chuck and a wafer, a doppler signal return, or a magnetic measurement.

The propagation wave 202 can be detected by various sensors such as a distance sensor (e.g., laser, ultrasonic, etc.) to detect a position of the top wafer 108 relative to the top chuck 102. The propagation sensors 406 can be disposed in the inner portion 118 or outer portion 114 along one or more radial axes of the top chuck 102. For example, a propagation sensor 406 can detect a position of a propagation wave 202 and can determine a speed of the propagation wave 202, based on an elapsed time relative to an engagement of a striker 106 or a detection of the propagation wave 202 at another propagation sensor 406. By positioning various propagation sensors 406 around various axes of the top chuck 102, a propagation wave 202 may be characterized (with regard to various outer portions 114). For example, separate propagation sensors 406 can be disposed over an axis for each outer portion 114, or the processor can interpolate a position of the propagation wave 202.

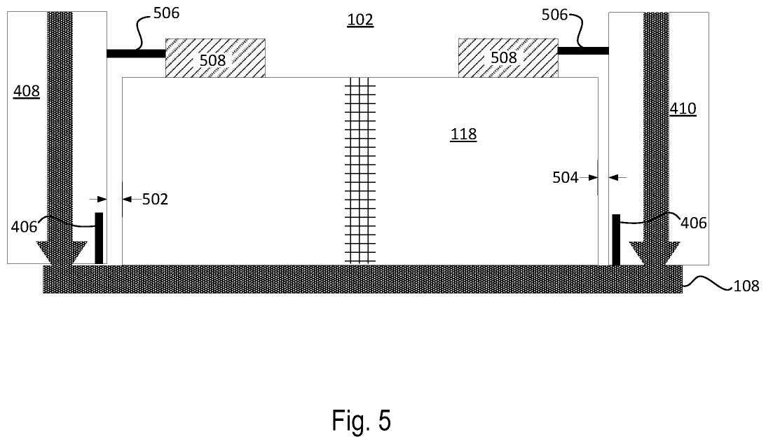

FIG. 5 illustrates a cross sectional view of a semiconductor chuck, in accordance with some embodiments. The outer portion 114 of the chuck is shown spaced from the inner portion 118 by a first inter-portion gap 502, opposite of a second inter-portion gap 504. The first inter-portion gap 502 extends a distance from the inner portion 118 to a first segment 408 of the outer portion 114. The second inter-portion gap 504 extends a distance from the inner portion 118 to a second segment 410. Such inter-portion gaps can be adjusted by a linear actuator in a same plane as the top wafer 108. For example, the linear actuator can be disposed along a face of the top chuck 102, opposite from the top wafer 108. The linear actuator can be coupled to the inner portion via a first coupler (not depicted), which can be integral to the body of the actuator or separate therefrom. The linear actuator can be coupled to the outer portion 114 via a second coupler 506, which can be integral to the body of the actuator or separate therefrom. The linear actuator can include a piezo electric actuator 508 which is electrically connected to a power source to adjust a signal applied thereto to cause a lateral displacement, thereby causing a lateral displacement of the segments of the outer portion 114. For example, the power source can be controlled by a controller of the top chuck 102, such as a processor 710 of FIG. 7.

In various embodiments, the propagation sensors 406 can include distance sensors (e.g., time of flight sensors, magnetic sensors, etc.) to detect a distance from the top chuck 102 to the top wafer 108. By determining a change in vertical distance, corresponding to the coupling of the top wafer 108 to the bottom wafer 110, the systems can determine a position of the propagation wave 202. In some embodiments, the propagation sensor 406 can directly measure the speed, as in the case of doppler sensors such as laser doppler vibrometers or ultrasonic frequency shift sensors. In various embodiments, the extension or contraction of the linear actuator can be responsive to a measured propagation wave 202 after a detection of the propagation wave 202 and prior to the arrival of the propagation wave 202 at the striker 106 or other wafer coupler of one or more of the segments. In some embodiments, a controller can cause the actuation of the linear actuator based on an elapsed time, wherein the elapsed time is based on other instances of a detected propagation wave 202.

In some embodiments, the controller can selectively engage one or more of the vacuum lines to cause the one or more of the vacuum pads to selectively couple to a wafer. For example, the controller can cause one or more of the vacuum lines of the top chuck 102 segments to selectively disengage responsive to a propagation wave 202. Such disengagement may be complete or partial (e.g., partial vacuum may be maintained) which can cause a decoupling between the top chuck 102 and the top wafer 108 to reduce stress imparted by the compressive force opposing the coupling therebetween. For example, the disengagement may be subsequent to an outward extension of the various segments, and be based on the propagation speed, direction, or so forth. For example, a radial distance along the top chuck 102 or top wafer 108 can define a release point for the one or more (e.g., all) vacuum pads 116 of the one or more segments.

In some embodiments, the inter-portion gaps 502, 504 can vary between the inner portion 118 and the first segment 408 and second segment 410. For example, the inter-portion gaps 502, 504 can vary according to a different speed or position of the propagation wave 202 (e.g., as depicted in FIG. 2). The inter-portion gaps 502, 504 can extend or contract to effect various stress profiles. For example, to reduce stress, the inter-portion gaps 502, 504 can be retracted to a local minimum prior to the actuation of the striker 106 (or other wafer coupling instantiation) and extended as the propagation wave 202 approaches the segments of the outer portion 114 (e.g., a vacuum pad 116 thereof).

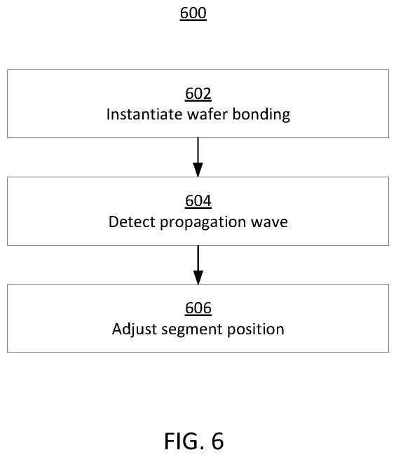

FIG. 6 illustrates a method 600 of wafer bonding, in accordance with some embodiments. In brief summary, the method 600 includes an instantiation of wafer bonding at operation 602, a detection of a propagation wave at operation 604, and an adjustment of a segment position at operation 606. It is noted that the method 600 is merely an example and is not intended to limit the present disclosure. Accordingly, it is understood that additional operations may be provided before, during, and after the method 600 of FIG. 6. Some operations may only be briefly described herein or may be omitted. For example, in some embodiments, the segment position may be adjusted separately from a detection of a propagation wave, such as embodiments which omit propagation wave sensors.

Referring again to operation 602, the method 600 includes instantiating wafer bonding between a first and second wafer. For example, the instantiation of the wafer bonding can be at an instantiation point, such as the center of a wafer, and can be caused by an engagement of a striker or a pressure or temperature applied to one or more of the first and second wafer. The wafer bonding may depend upon a bonding type. For example, permanent bonding can include thermocompression bonding or anodic bonding; temporary bonding can include mechanical or other bonding techniques, either of which may include propagating outward from a central point of contact of the wafer. The first wafer can be coupled to various segments of a wafer chuck, such as segments of an outer portion which circumscribes a fixed inner portion.

Referring again to operation 604, the method 600 includes detecting a propagation wave from the instantiation point. For example, the propagation wave may refer to a propagation of a coupling between the two wafers. According to various embodiments, the propagation wave can be observed optically, magnetically, electrically, or so forth. For example, a distance between one or more of the wafers and a fixed portion of a chuck can be measured. The distance can be compared to a threshold, such as a predefined threshold, or a previously measured value such that a relative change in position is indicative of the propagation wave (e.g., to operate with wafers of various thickness).

Referring again to operation 606, the method 600 includes adjusting the position of one or more of the plurality of segments of the wafer chuck, responsive to the detection of the propagation wave. For example, the adjustment can include an adjustment to control a stress profile of one or more of the wafers (e.g., to add or reduce residual stress imparted into a bonded wafer). In some embodiments, the adjustment can include an actuation of a linear actuator such as a piezo electric element, to increase a dimension between the fixed portion of the wafer chuck so as to prevent compression of the wafer as the propagation wave radially extends to the adjustable segment. That is, the adjustment may be performed prior to the arrival of the propagation wave at each of the one or more of the plurality of segments.

FIG. 7 illustrates a block diagram illustrating an architecture for a computer system that can be employed to implement elements of the systems and methods described and illustrated herein. The computer system or computing device 700 can include or be used to implement a controller or its components, and components thereof, which can interface with a top chuck 102 or other component of the systems 100 and methods described herein. The computing system 700 includes at least one bus 705 or other communication component for communicating information and at least one processor 710 or processing circuit coupled to the bus 705 for processing information. The computing system 700 can also include one or more processors 710 or processing circuits coupled to the bus for processing information. The computing system 700 also includes at least one main memory 715, such as a random access memory (RAM) or other dynamic storage device, coupled to the bus 705 for storing information, and instructions to be executed by the processor 710. The main memory 715 can be used for storing information during execution of instructions by the processor 710. The computing system 700 may further include at least one read only memory (ROM) 720 or other static storage device coupled to the bus 705 for storing static information and instructions for the processor 710. A storage device 725, such as a solid state device, magnetic disk or optical disk, can be coupled to the bus 705 to persistently store information and instructions.

The computing system 700 may be coupled via the bus 705 to a display 735, such as a liquid crystal display, or active matrix display. An input device 730, such as a keyboard or mouse may be coupled to the bus 705 for communicating information and commands to the processor 710. The input device 730 can include a touch screen display 735.

The processes, systems and methods described herein can be implemented by the computing system 700 in response to the processor 710 executing an arrangement of instructions contained in main memory 715. Such instructions can be read into main memory 715 from another computer-readable medium, such as the storage device 725. Execution of the arrangement of instructions contained in main memory 715 causes the computing system 700 to perform the illustrative processes described herein. One or more processors in a multi-processing arrangement may also be employed to execute the instructions contained in main memory 715. Hard-wired circuitry can be used in place of, or in combination with, software instructions together with the systems and methods described herein. Systems and methods described herein are not limited to any specific combination of hardware circuitry and software.

Although an example computing system has been described in FIG. 7, the subject matter including the operations described in this specification can be implemented in other types of digital electronic circuitry, or in computer software, firmware, or hardware, including the structures disclosed in this specification and their structural equivalents, or in combinations of one or more of them.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor chuck for fabricating semiconductor devices, comprising:
a first portion comprising a plurality of first couplers configured to receive a corresponding plurality of actuators;
a second portion circumscribed about the first portion, the second portion comprising a plurality of segments comprising:
a wafer holder to selectively couple the respective segment to a semiconductor wafer; and
a second coupler to receive one or more of the plurality of actuators, wherein the plurality of actuators are configured to:
extend to increase a dimension between the first portion and the second portion; and
retract to decrease the dimension between the first portion and the second portion.

2. The semiconductor chuck of claim 1, wherein the plurality of actuators comprise a piezo electric element.

3. The semiconductor chuck of claim 1, wherein the wafer holder comprises a vacuum pad.

4. The semiconductor chuck of claim 1, configured to interface with one or more processors configured to:
cause a striker to displace the semiconductor wafer from the facing; and
cause an actuation of the wafer holders to decouple from the semiconductor wafer subsequent to the displacement of the semiconductor wafer at the striker, and prior to an arrival of a propagation wave at the wafer holders.

5. The semiconductor chuck of claim 4, further comprising:
a sensor to detect the propagation wave, wherein the actuation of the wafer holders is responsive to a signal detected by the sensor.

6. The semiconductor chuck of claim 4, further comprising:
a first sensor to detect a wafer height at a first point along the semiconductor wafer;
a second sensor to detect a second wafer height at a second point along the semiconductor wafer disposed radially outward from the first sensor; and
the one or more processors to determine a propagation speed based on an elapsed time between a first detection of the first sensor and a second detection of the second sensor.

7. The semiconductor chuck of claim 1, wherein:
a first of the plurality of actuators is configured to extend a first distance; and
a second of the plurality of actuators is configured to extend a second distance, different from the first distance.

8. The semiconductor chuck of claim 1, wherein:
a first of the plurality of actuators is configured to extend at a first rate, and
a second of the plurality of actuators is configured to extend at a second rate, different from the first rate.

9. The semiconductor chuck of claim 1, configured to interface with one or more processors configured to:
cause a striker to displace the semiconductor wafer from the facing; and
cause an actuation of the actuators to decouple the semiconductor wafer subsequent to the displacement of the semiconductor wafer at the striker.

10. A system, comprising:
a semiconductor chuck for fabricating semiconductor devices, the semiconductor chuck comprising:
an inner portion;
an outer portion comprising a plurality of segments, each of the plurality of segments being coupled to the inner portion by a respective actuator; and
one or more processors coupled with memory configured to:
detect an indication of a propagation wave; and
engage one or more of the actuators responsive to the detection.

11. The system of claim 10, wherein:
the actuators comprise a piezo electric element.

12. The system of claim 10, wherein the detection of the indication of the propagation wave comprises:
a detection of a time elapsed from an instantiation of the propagation wave of a first wafer.

13. The system of claim 12, wherein the detection of the instantiation of the propagation wave is incident to an engagement, by the one or more processors, of a striker.

14. The system of claim 10, wherein the detection of the indication of the propagation wave comprises:
a detection of a distance between the semiconductor chuck and a first wafer; and
a comparison of the distance to a threshold.

15. The system of claim 10, wherein the detection of the indication of the propagation wave comprises:
a detection of the propagation wave at a first point along a first wafer;
a detection of the propagation wave at a second point along the first wafer, along a same axis as the first point; and
a determination of a time elapsed between the first point and the second point.

16. The system of claim 10, wherein the indication of the propagation wave comprises an indication of propagation wave in a plurality of radial directions of a first wafer.

17. The system of claim 10, further comprising the one or more processors to:
selectively engage the wafer holders responsive to the indication of the propagation wave.

18. A method, comprising:
instantiating, at an instantiation point, wafer bonding between a first wafer and a second wafer, wherein the first wafer is coupled to a plurality of segments of a wafer chuck which are coupled to a fixed portion of the wafer chuck;
detecting a propagation wave originating from the instantiation point; and
adjusting a position of one or more of the plurality of segments of the wafer chuck responsive to the detection of the propagation wave.

19. The method of claim 18, wherein:
instantiating the wafer bonding comprises engaging a striker to deflect the first wafer towards the second wafer; and
the detection of the propagation wave comprises detecting a distance from the first wafer to the wafer chuck in a plurality of axes of the first wafer.

20. The method of claim 18, wherein:
the plurality of segments of the wafer chuck are coupled to the fixed portion of the wafer chuck by a plurality of piezo electric actuators; and
the adjustment to the position of the one or more of the plurality of segments is performed prior to an arrival of the propagation wave at each of the one or more of the plurality of segments.
